(19) United States
(12) Patent Application Publication
(10) Pub. No.: US 2006/0176675 A1
(43) Pub. Date: Aug. 10, 2006

(54) Multi-layer polymeric electronic device and method of manufacturing same

(75) Inventors: Gordon Bourns, Riverside, CA (US); Gary Straker, Riverside, CA (US); Ray Burke, Co Cork (IE); Thanh Nguyen, Pomona, CA (US)

Correspondence Address: KLEIN, O'NEILL & SINGH, 2 PARK PLAZA, SUITE 510, IRVINE, CA, 92614, US

(73) Assignee: Bourns, Inc., Riverside, CA (US)

(21) Appl. No.: 10/548,971

(22) PCT Filed: Mar. 15, 2004
(86) PCT No.: PCT/US04/07764

§ 371 Date: Sep. 13, 2005

Related U.S. Application Data
(60) Provisional application No. 60/454,865, filed on Mar. 14, 2003.

(51) Int. Cl. H05K 7/06; H05K 3/36; H05K 1/03

(52) U.S. Cl. 361/780; 29/852; 29/830; 361/795; 174/260; 174/256; 174/255

(57) ABSTRACT

An electronic device is formed of multiple, alternating layers of conductive polymer and metal foil electrodes, in which electrical connections between selected electrodes are provided by cross-conductors formed by plated through-hole vias. More specifically, the device includes a first cross-conductor that electrically connects a first set of electrodes, and a second cross-conductor electrically connects a second set of electrodes. Correspondingly, the first cross-conductor is electrically and physically isolated from the second set of electrodes, while the second cross-conductor is electrically and physically isolated from the first set of electrodes. The electrodes are etched to form an isolation gap that isolates that electrode from either the first or second cross-conductor. The first and second cross-conductors, in turn, are formed by plating the through-hole vias, so as to establish electrically-conductive contact with those electrodes not separated from the via by an isolation gap. Thus, a device may be formed with N non-metallic (e.g. polymeric) layers and N+1 electrodes, where N is an integer greater than 1, wherein a first cross-conductor electrically contacts a first set of electrodes, and a second cross-conductor electrically contacts a second set of electrodes, whereby the non-metallic layers are connected in parallel.

### CROSS-REFERENCE TO RELATED APPLICATION

This application claims the benefit, under 35 U.S.C. Section 119(e), of co-pending U.S. Provisional Application No. 60/454,754, filed Mar. 14, 2003, the disclosure of which is incorporated herein by reference.

### FEDERALLY SPONSORED RESEARCH OR DEVELOPMENT

Not Applicable

### BACKGROUND OF THE INVENTION

The present invention relates to a multi-layer polymeric electronic device or component and a method of manufacturing it. Specifically, the present invention relates (a) to a method of manufacturing multi-layer polymeric electronic devices using a process that employs plated through-hole vias to create conductive paths between selected laminar electrodes; and (b) to a multi-layer polymeric electronic device made in accordance with the method of the invention. More specifically, the invention relates to a laminar electronic device comprising two or more polymeric active elements laminated between laminar metal (e.g., foil) layers that form electrodes, wherein the device includes a first conductive path that provides electrical connections between a first plurality of metal layers that form a first set of electrodes, and a second conductive path that provides electrical connections between a second plurality of metal layers that form a second set of electrodes. Correspondingly, the first conductive path is physically and electrically isolated from the second plurality of metal layers, while the second conductive path is physically and electrically isolated from the first plurality of metal layers.

Electronic devices or components employing conductive polymer elements, especially elements exhibiting positive temperature coefficient of resistivity (PTC) behavior, are well-known in the art. Typically, such devices comprise a laminated structure formed from a layer of conductive polymer material laminated between metal foil layers that function as electrodes. Terminations are then formed on the device for electrical connection to a circuit board, usually in a surface-mount configuration. For the purposes of both electrical efficiency and space-saving, multi-layer components are becoming increasingly common. Such multi-layer components typically comprise at least two discrete laminar polymeric elements, separated by laminar foil electrodes, and terminated by conductive terminations for connection to a circuit board. Such devices are preferably vertically and laterally symmetrical; that is, they have no distinct “right side up,” “upside down,” or “end-to-end” orientations, for more efficient installation on a circuit board by “pick-and-place” machinery. Exemplary prior art devices and methods of manufacturing them are disclosed in the following patent publications: U.S. Pat. No. 6,640,420; U.S. Pat. No. 6,172,591; U.S. Pat. No. 6,020,808; U.S. Pat. No. 6,429,533; and U.S. Pat. No. 6,242,997.

For maximum cost-savings, such devices must be easily mass-produced, typically with hundreds of such devices being formed simultaneously from a single laminated sheet structure. Heretofore, however, the need to create inter-layer conductive paths has presented challenges in reducing manufacturing costs, and thus more cost-efficient manufacturing methods are continually being sought. Furthermore, there has been a desire in the industry to apply multi-layer manufacturing techniques to a wider variety of electrical components and devices.

### SUMMARY OF THE INVENTION

Broadly, the present invention is an electronic device or component comprising multiple, alternating layers of non-metallic (e.g., polymeric) material and metal foil electrodes, in which electrical connections between selected electrodes are provided by cross-conductors formed by plated through-hole vias. More specifically, the invention relates to a laminar electronic device comprising two or more non-metallic (e.g., polymeric) laminar elements laminated between metal foil layers that form electrodes, wherein the device includes a first cross-conductor, passing through a first through-hole via, that provides electrical connections between a first plurality of metal layers that form a first set of electrodes, and a second cross-conductor, passing through a second through-hole via, that provides electrical connections between a second plurality of metal layers that form a second set of electrodes. Correspondingly, the first cross-conductor is electrically and physically isolated from the second plurality of metal layers, while the second cross-conductor is electrically and physically isolated from the first plurality of metal layers.

The electrodes are formed by metal foil layers that are etched to form an isolation gap in each foil layer that isolates that layer from either of the first or second vias. The first and second cross-conductors, in turn, are formed by plating the through-hole vias, so as to establish electrically-conductive contact with those electrodes not separated from the via by an isolation gap. Thus, a device may be formed with N non-metallic (e.g. polymeric) layers and N+1 electrodes, where N is an integer greater than 1, wherein a first cross-conductor through a first via establishes electrical contact with a first set of N electrodes, and a second cross-conductor through a second via establishes electrical contact with a second set of N−1 electrodes, whereby the non-metallic layers are connected in series or parallel.

In a preferred embodiment, the plating that forms the cross-conductors through the vias also forms terminals or contact pads on the opposed major external surfaces of the device. The contact pads allow the device to be surface-mounted on a circuit board.

In the preferred embodiments, at least one of the non-metallic layers is made of a conductive polymer, such as a carbon-filled polymer that exhibits PTC behavior, as disclosed in, for example, U.S. Pat. No. 5,849,129; U.S. Pat. No. 4,237,441; and U.S. Pat. No. 5,174,924, the disclosures of which are incorporated by reference. Some embodiments may include one or more non-conductive (dielectric) polymeric layers, or conductive polymeric layers that have a fixed resistance, or ferromagnetic polymeric layers. Other embodiments may include still other types of laminar elements, such as, for example, a metal oxide varistor (MOV). Thus, the cross-conductors may be formed so as to create a device that comprises one or more elements that may include, for example, PTC elements, ferromagnetic elements, capacitive elements, fixed resistive elements, or non-polymeric active elements, connected in series or in parallel.

As will be appreciated from the detailed description below, the present invention provides a cost-efficient method of manufacturing multi-layer laminar electronic components that are also highly space-efficient. Moreover, the method of the invention offers a great deal of flexibility in manufacturing devices of a wide variety of electrical properties and characteristics in a single, space-saving package that is, preferably, vertically and/or laterally symmetrical, thereby resulting in advantages in installing the devices on circuit boards using conventional pick-and-place machinery. These and other advantages will be more fully understood from the following detailed description.

### BRIEF DESCRIPTION OF THE DRAWINGS

FIG. 1 is a perspective view of a laminated structure or sheet comprising a layer of conductive polymer material laminated between upper and lower laminar metal layers;

FIG. 1A is a perspective view of the laminated structure of FIG. 1, showing the structure after a grid of singulation lines has optionally been formed on at least one of the metal layers;

FIG. 2 is an exploded, cross-sectional view of the laminated structures used to form a multi-layer device manufactured in accordance with a first embodiment of the present invention, prior to the lamination together of the two laminated structures;

FIG. 2A is a cross-sectional view of a finished multi-layer device in accordance with the first embodiment of the invention;

FIG. 3 is a top plan view of the device of FIG. 2A;

FIG. 4 is a cross-sectional view of a multi-layer device manufactured in accordance with the first embodiment of the present invention, embodied in a device having three polymeric layers;

FIG. 5 is a top plan view of the device of FIG. 4;

FIG. 6 is a cross-sectional view of a multi-layer device manufactured in accordance with another embodiment of the present invention;

FIG. 7 is a top plan view of the device of FIG. 6;

FIG. 8A is a cross-sectional, exploded view of the laminated structures used in manufacturing a multi-layer device in accordance with a third embodiment of the present invention;

FIG. 8B is an exploded, cross-sectional view, similar to that of FIG. 8A, showing the device after the step of etching the metal layers and forming isolation areas, and before the final lamination step;

FIG. 9 is a cross-sectional view of a finished multi-layer device constructed in accordance with the third embodiment of the present invention;

FIG. 10 is a cross-sectional view of a multi-layer polymeric capacitor in parallel with an integrated multi-layer metal oxide varistor (MOV);

FIG. 11 is a cross-sectional view of multi-layer electronic device, constructed in accordance with the present invention, in which the device comprises a polymeric positive temperature coefficient (PPTC) element in series with a fixed resistive element;

FIG. 12 is a cross-sectional view, taken along line 12-12 of FIG. 13, of a multi-layer electronic device, similar to that of FIG. 11, but comprising multiple PPTC elements in parallel with each other and in series with a fixed resistive element;

FIG. 13 is a cross-sectional view taken along line 13-13 of FIG. 12;

FIG. 14 is a cross-sectional view of a modified form of the device of FIGS. 12 and 13;

FIG. 15 is a cross-sectional view taken along line 15-15 of FIG. 14; and

FIG. 16 is a cross-sectional view of another modified form of the device of FIGS. 12 and 13.

### DETAILED DESCRIPTION OF THE INVENTION

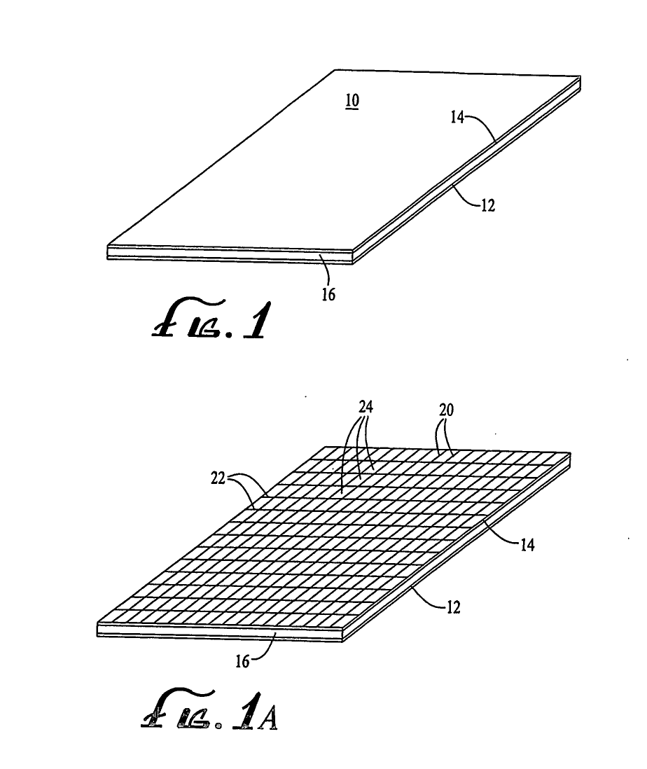

The various embodiments of the present invention are made with one or more laminated sheet structures, of the type shown in FIG. 1. As shown, a laminated sheet structure 10 comprises a layer of polymeric active material 16 laminated between a lower laminar metal layer 12 and an upper laminar metal layer 14. The polymeric layer 16 may be a conductive polymer, such as a polymeric positive temperature coefficient (PTC) resistive material, or it may be a polymeric dielectric material, or a ferromagnetic polymer. Various types of suitable polymer materials are well-known in the art. The metal layers 12, 14 are preferably made of conductive metal foil, and more preferably a nickel-plated copper foil that is nodularized (by conventional techniques) on the surface that is placed against the polymeric layer. The lamination may be performed by any suitable lamination process known in the art, an example of which is described in International Patent Publication No. WO 97/06660, the disclosure of which is incorporated herein by reference.

As an alternative to laminating a layer of polymeric material between upper and lower foil sheets, it may be advantageous, for certain applications, to metallize directly the upper and lower surfaces of a sheet of polymeric material. The metallization may be accomplished by a metal plating process, vapor deposition, screen-printing, or any other suitable process that may suggest itself to those skilled in the pertinent arts. The preferred embodiments of the invention, however, use the laminated structure described above, and the ensuing description will be based on the use of the lamination process.

The laminated sheet structure 10 is typically sized to provide a multitude of electronic devices. Thus, as shown in FIG. 1A, the sheet 10 may advantageously be provided with a grid of optional singulation lines 20, 22, which are formed in one or both of the metal layers 12, 14, and which will serve to define a plurality of devices 24. The singulation lines 20, 22 may be formed by conventional photo-resist and etching techniques, and are preferably of sufficient width to provide a small space or “isolation barrier” which is formed along the edges of each device 24 after singulation. The isolation barrier minimizes the probability of a short occurring between adjacent conductive elements (electrodes or terminals, as will be described) for which electrical isolation is desired.

The devices described below are advantageously mass-produced while interconnected in a matrix formed by the lamination of two or more sheet structures into a laminated structure, which is then singulated (e.g., along the lines 20, 22) to form individual devices. The discussion below will be set forth with reference to the illustration of a single device, but it is to be understood that the process steps described below are performed on a matrix of such devices while they are interconnected in such a matrix. Thus, each step is performed simultaneously at a plurality of pre-defined locations on the matrix. As a final step in the manufacturing processes described below, the individual devices are separated from the matrix (singulated) by cutting, breaking, or dicing the matrix along the singulation lines 20, 22, or along a grid of separation lines defined by the singulation apparatus (if the singulation lines are not pre-formed).

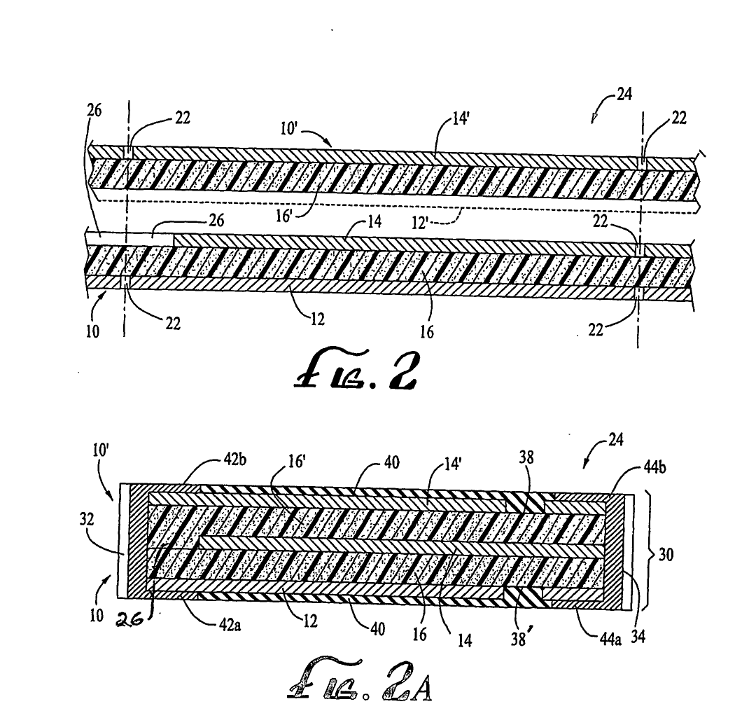

Referring now to FIGS. 2, 2A, and 3, a device 24 in accordance with a first embodiment of the invention is shown. The device comprises a first sheet structure 10, comprising a first layer of non-metallic (e.g., polymeric) material 16 sandwiched between a first lower metal layer 12 and a first upper metal layer 14, with optional singulation lines 20, 22. Portions of the first upper metal layer 14 at pre-defined isolation area locations are removed to form an isolation area 26 (FIGS. 2, 2A, and 3) for each device. The isolation area 26 is advantageously bisected by a singulation line 22, and has a radius that is preferably approximately equal to the thickness of the first polymer layer 16. The center point of the isolation layer 26 may thus be located where a through-hole via will be formed, as will be described below.

A second sheet structure 10′ is provided, having a second upper metal layer 14′ on top of a second non-metallic (e.g., polymeric) layer 16′. The second sheet structure 10′ may be formed by laminating the second non-metallic layer 16′ between the second upper metal layer 14′, and a second lower metal layer 12′, but, after its lamination, the second lower metal layer 12′ (shown in phantom outline) of the second sheet structure 10′ is removed, by a conventional process, leaving only the second polymer layer 16′ and the second upper metal layer 14′, as shown in FIG. 2. The second laminated sheet structure 10′ may also advantageously be provided with a grid of singulation lines 20, 22 (although only the singulation lines 22 are shown in FIG. 2). The second sheet structure 10′ is then laminated to the first sheet structure 10, with the second polymer layer 16′ of the second sheet structure 10′ joined to the first upper metal layer 14 of the first sheet structure 10, to form a multi-layer laminated structure 30, as shown in FIGS. 2A and 3, in which the singulation lines 20, 22 of both sheet structures 10, 10′ are in registry. As a result of this lamination, polymeric material from the polymer layers 16, 16′ melts and flows into and fills the isolation areas 26, as shown in FIG. 2A. In accordance with standard industry practices, the top surface of the first upper metal layer 14 may be “nodularized” (formed with micro-nodules) to improve adhesion with the second polymer layer 16′, or a conductive adhesive may be used for the same purpose.

It is understood that the second sheet structure 10′ may alternatively be made by directly metallizing the top surface of a sheet of polymeric material by any of the conventional methods mentioned above with respect to the first sheet structure 10.

After the multi-layer laminated structure 30 is formed, a plurality of through-hole vias is formed at pre-defined via locations in the structure 30. The plurality of vias includes a first subset of vias 32, each of which passes through one of the isolation areas 26, as mentioned above. The plurality of vias includes a second subset of vias 34, each of which passes through the multi-layer structure 30 at a pre-defined distance from one of the first subset of vias 32, such as may be defined, for example, by a singulation line 22 (FIG. 2) defining the opposite end of the device. At this point, the inside surfaces of the through-hole vias 32, 34 may be metallized with a first layer of a conductive metal, preferably copper, by any suitable process, such as electroplating. Thus, a first set of electrically conductive interconnections or “cross-conductors” is formed in the first plated through-hole vias 32, each of which electrically connects the lower metal layer 12 and the second upper layer 14′, while a second set of electrically conductive interconnections (“cross-conductors”) is formed in the second plated through-hole vias 34, each of which electrically connects the lower metal layer 12, the first upper metal layer 14 (which now may be defined as the intermediate metal layer), and the second upper metal layer 14′. Each of the first plated through-hole vias 32 is insulated, however, from the intermediate metal layer 14 by the polymeric material that occupies the isolation area 26. Alternatively, this first metallizing step may be omitted, and the metallization of the vias deferred until the terminal plating step described below

Using conventional photo-resist masking and etching techniques, or any other suitable process known in the art, metal is removed from the lower metal layer 12 and the second upper metal layer 14′ to form a set of transverse top isolation gaps 38 across the entire width of the second upper metal layer 14′ and a set of transverse bottom isolation gaps 38′ across the entire width of the lower metal layer 12. Each of the isolation gaps 38, 38′ is formed at a relatively short, pre-defined distance from one of the vias 34 in the second subset of vias, and they have a width (i.e., the dimension parallel to the longer dimension of the device) that is preferably approximately equal to the thickness of the polymer layers 16, 16′.

A solder mask 40, which is preferably a dielectric material, is screen-printed, or otherwise applied, to the lower metal layer 12 and to the second upper metal layer 14′, so as to fill in the isolation gaps 38, 38′, but leaving an exposed metal area surrounding each of the vias 32, 34. Specifically, the areas of the lower metal layer 12 and second upper metal layer 14′ between the respective isolation gaps 38, 38′ and the end of each device that is closer to the isolation gaps 38, 38′ are left exposed, as are the approximately equal-sized areas of the lower metal layer 12 and the second upper metal layer 14′ at the opposite end of each device. The exposed metal areas are coated (as by plating), first with nickel, and then with a solderable metal (e.g., gold), in accordance with standard industry practices, thereby forming a first pair of terminal pads 42a, 44a at each end of the lower surface of the device, and similar second pair of terminal pads 42b, 44b at each end of the upper surface of the device. The same plating layers are applied at the same time to the through-hole vias 32, 34. As mentioned above, the through-hole vias 32, 34 may have been previously metallized before the formation of the isolation gaps 38, 38′, and if so, the vias 32, 34 are metallized a second time when the exposed areas of the second upper metal layer 14′ and the lower metal layer 12 are metallized.

After completion of the above-mentioned metallization step, it can be seen that a first set of terminals is formed, each of which comprises a first lower terminal pad 42a, a first upper terminal pad 42b, and the electrical connection or cross-conductor therebetween provided by a metallized first through-hole via 32. In each device in the matrix, each of these first terminals thus electrically connects the lower metal layer 12 (which now defines a lower electrode) and the second upper metal layer 14′ (which now defines an upper electrode). Each of the first terminals is isolated, however, from the intermediate metal layer 14 (which now defines an intermediate electrode) by the polymer-filled isolation area 26. Likewise, a second set of terminals is formed, each of which comprises a second lower terminal pad 44a, a second upper terminal pad 44b, and the electrical interconnection or cross-conductor formed therebetween by a metallized second through-hole via 34. This second terminal is in electrical contact with the intermediate electrode (intermediate or second metal layer) 14, but it is isolated from the upper and lower electrodes by the isolation gaps 38, 38′, respectively (both of which are filled by the solder mask material 40).

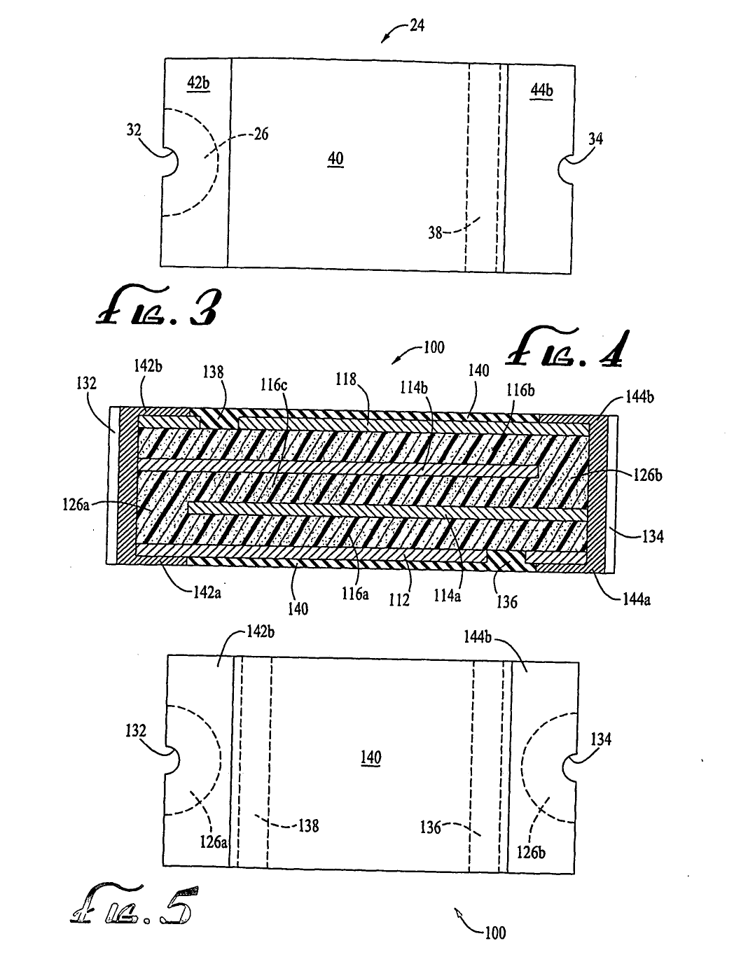

FIGS. 4 and 5 illustrate a multi-layer device 100 having three polymer layers, i.e., a lower polymer layer 116a, an upper polymer layer 116b, and an intermediate polymer layer 116c. The device 100 is constructed in a manner that is a slight variation of the above-described manufacturing method. To form the device 100, two complete sheet structures 10, 10′ (FIG. 2), including the second lower metal layer 12′, are laminated together with the intermediate polymer layer 116c between them. Thus, each device in the matrix comprises a lower metal layer 112 forming a lower electrode, the lower polymer layer 116a, a first intermediate metal layer 114a forming a first intermediate electrode, the intermediate polymer layer 116c, a second intermediate metal layer 114b forming a second intermediate electrode, the upper polymer layer 116b, and an upper metal layer 118 forming an upper electrode.

In this configuration, each device is formed with a first arcuate isolation area 126a at one end of the first intermediate metal layer 114a, and a second arcuate isolation area 126b at the opposite end of the second intermediate metal layer 114b. The isolation areas 126a, 126b are formed in their respective metal layers 114a, 114b before the lower and upper sheet structures 10, 10′ are laminated together with the intermediate polymer layer 116c between them to form a laminated structure. The lamination of the sheet structures 10, 10′ causes polymeric material to flow into and fill the isolation areas 126a, 126b. After the two complete sheet structures 10, 10′ are laminated together with the intermediate polymer layer 116c between them, first and second subsets of through-hole vias 132, 134 are formed through the entire thickness of the laminated structure and metallized, as described above.

At each of a plurality of pre-defined locations in the laminated structure, a set of bottom isolation gaps 136 is formed in the lower metal layer 112, and a set of top isolation gaps 138 is formed in the upper metal layer 118. The bottom isolation gaps 136 are adjacent to, and on either side of, each of the second subset of vias 134, while the top isolation gaps 138 are adjacent to, and on either side of, each of the first subset of vias 132. A layer of solder mask material 140 (e.g., a dielectric material) is applied to both the lower metal layer 112 and the upper metal layer 118, filling in the isolation gaps 136, 138, and leaving exposed metal areas on the lower and upper metal layers 112, 118 surrounding each of the vias 132, 134. The exposed metal areas are then plated (or otherwise metallized), first with nickel, and then with a solderable metal, such as gold, to form first and second lower terminal pads 142a, 144a and first and second upper terminal pads 142b, 144b. The through-hole vias 132, 134 are metallized (e.g., plated) with the nickel and the solderable metal at the same time as the exposed metal end areas.

Thus, each of the devices 100 has a first terminal formed by the first lower terminal pad 142a, the first upper terminal pad 142b, and the electrical interconnection or cross-conductor formed between them by the plated first through-hole via 132. Likewise, a second terminal is formed by the second lower terminal pad 144a, the second upper terminal pad 144b, and the electrical interconnection or cross-conductor formed between them by the plated second through-hole via 134. The first terminal provides electrical connection to the lower metal layer 112 (which may now be defined as a lower external electrode) and to the second intermediate metal layer 114b (which may now be defined as a second intermediate electrode or a second internal electrode). Similarly, the second terminal provides electrical connection to the upper metal layer 118 (which may now be defined as an upper external electrode) and to the first intermediate metal layer 114a (which may now be defined as a first intermediate electrode or a first internal electrode). The first terminal is electrically isolated from the first internal electrode 114a by the polymer-filled first isolation area 126a, and from the upper electrode 118 by the second isolation gap 138. Similarly, the second terminal is electrically isolated from the lower electrode 112 by the first isolation gap 136, and from the second internal electrode 114b by the polymer-filled second isolation area 126b.

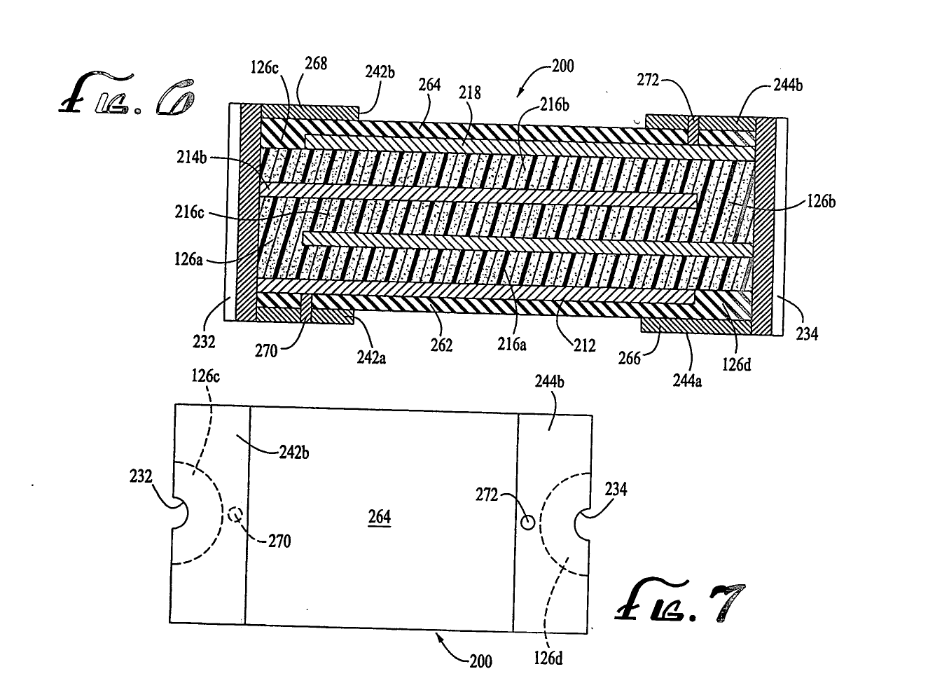

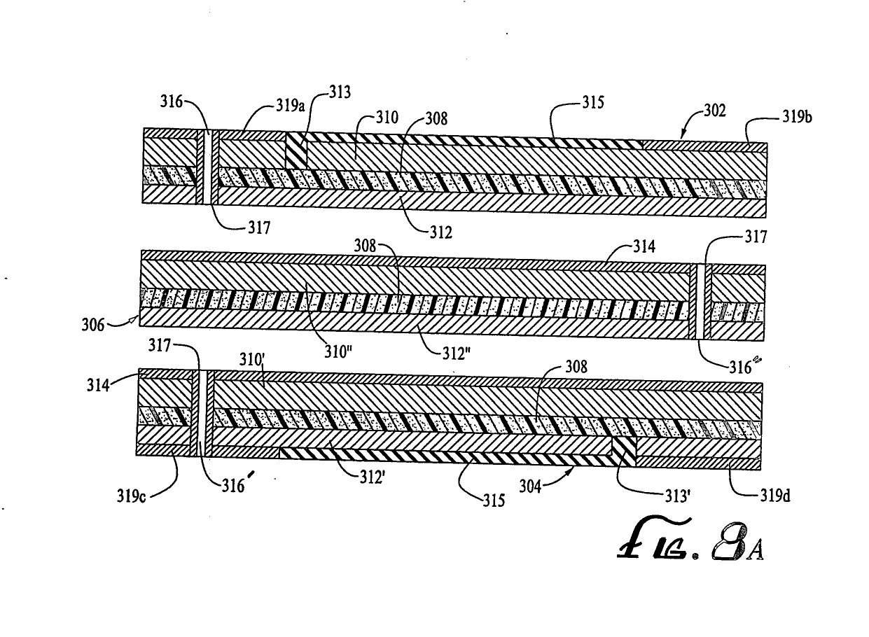

FIGS. 6 and 7 show a multi-layer device 200 constructed in accordance with another embodiment of the invention. This embodiment is similar to that of FIGS. 4 and 5, except that instead of using the transverse isolation gaps 136, 138 to define the terminal pads 142a, 142b, 144a, 144b, the device 200 of this embodiment includes an upper metal layer 218 having a third isolation area 126c that is centered at a first through-hole via 232, and a lower metal layer 212 having a fourth isolation area 126d formed at the opposite end, centered at a second through-hole via 234. A bottom layer of insulating material 262 is formed (by conventional techniques) on the surface of the lower metal layer 212, and a top layer of insulating material 264 is similarly formed on the surface of the upper metal layer 218. The insulating layers 262, 264 may advantageously be formed of prepreg. A bottom external metal foil layer 266 and a top external metal foil layer 268 are laminated onto the first and second insulating layers 262, 264, respectively. Alternatively, the bottom external foil layer 266 may be laminated to the bottom insulating layer 262 before the latter is laminated to the lower metal layer 212, and the top external foil layer 268 may similarly be laminated to the top insulating layer 264 before the latter is laminated to the upper metal layer 218. During the step of laminating the insulating layers 262, 264 to the metal layers 212, 218, respectively, the prepreg material is caused to flow into and fill the third and fourth isolation areas 126c, 126d.

First and second sets of through-hole vias 232, 234 are then respectively drilled or otherwise formed at matrix locations that will correspond to opposite ends of each device 200 in the matrix. A first micro-via 270 may advantageously be formed through the bottom external foil layer 266 and the adjacent first insulating layer 262 at the end of each device 200 opposite the fourth isolation area 126d, and a second micro-via 272 may advantageously be formed through the top external foil layer 268 and the second insulating layer 264 at the end of each device opposite the third isolation area 126c. The first micro-via 270 extends to the surface of the lower metal layer (lower electrode 212), while the second micro-via 272 extends to the surface of the upper metal layer (upper electrode 218). The through-hole vias 232, 234, and the micro-vias 270, 272 are plated, first with a copper seed layer, then with a nickel layer, and then with a solderable metal, such as gold.

The bottom external foil layer 266 and the top external foil layer 268 are masked and etched to define a pair of lower terminal pads 242a, 244a, and a pair of upper terminal pads 242b, 244b. The upper terminal pads 242b, 244b are connected to their respective lower terminal pads 242a, 244a by the plated through-hole vias 232, 234, respectively, which also make contact with the metal layers that form the electrodes, whereby first and second terminals are formed. Specifically, a first terminal comprises the first lower terminal pad 242a, the first upper terminal pad 242b, and a first cross-conductor formed by the first plated through-hole via 232; while a second terminal comprises the second lower terminal pad 244a, the second upper terminal pad 244b, and a second cross-conductor formed by the second plated through-hole via 234. The first terminal makes contact with a second internal metal layer 214b that serves as a second intermediate electrode, and with the lower metal layer 212 that serves as a lower electrode. The second terminal makes contact with a first internal metal layer 214a that serves as a first intermediate electrode, and with the upper metal layer 218 that serves as an upper electrode. Furthermore, the first plated through-hole via 232 is insulated from the first intermediate electrode 214a by the polymer-filled first isolation area 126a (as explained above with respect to FIGS. 4 and 5), and from the upper electrode 218 by the prepreg-filled third isolation area 126c. Likewise, the second plated through-hole via 234 is insulated from the lower electrode 212 by the prepreg-filled fourth isolation area 126d, and from the second intermediate electrode 214b by the polymer-filled second isolation area 126b.

The embodiment of FIGS. 6 and 7 is shown with a first or lower polymer layer 216a between the lower electrode 212 and the first intermediate electrode 214a; a second or upper polymer layer 216b between the upper electrode 218 and the second intermediate electrode 214b, and a third or intermediate polymer layer 216c between the two intermediate electrodes 214a, 214b. It will be appreciated that a device having N polymer (or, more generally, non-metallic) layers and N+1 electrodes (where N is an integer greater than 1) can be constructed in accordance with the embodiment of FIGS. 6 and 7. Furthermore, this manner of construction maximizes the area of the electrodes that is in contact with the adjacent polymer layers.

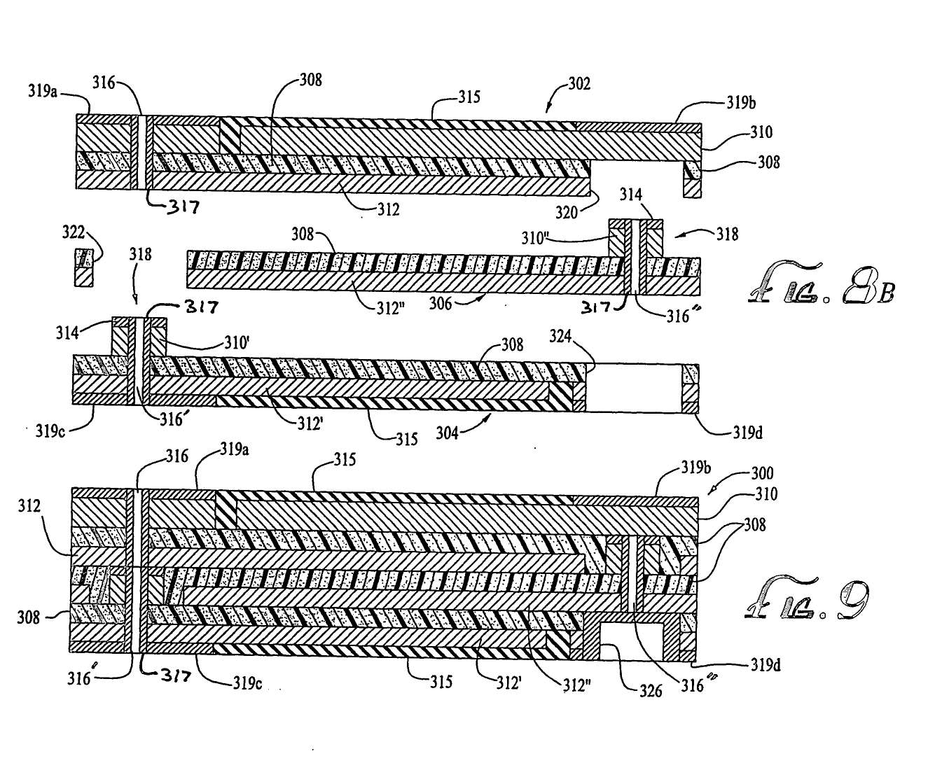

FIGS. 8A, 8B, and 9 illustrate an embodiment that is advantageous for the construction of a multi-layer device 300 (shown assembled in FIG. 9), in which the polymer layers are slightly thinner than the foil layers. Referring first to FIG. 8A, the illustrated exemplary embodiment comprises an upper laminated substructure 302, a lower laminated substructure 304, and an intermediate laminated substructure 306. Each of the laminated substructures 302, 304, 306 comprises a polymer layer 308 laminated between first, second, and third top metal foil layers 310, 310′ and 310″, respectively, and first, second and third bottom metal foil layers 312, 312′ and 312″, respectively. The lower surfaces of the first, second, and third top foil layers 310, 310′, and 310″ are advantageously nodularized with micro-nodules, in accordance with conventional manufacturing techniques, as are both surfaces of the first and third bottom foil layers 312, 312″, and the upper surface of the second bottom foil layer 312′. The thickness of each of the top metal foil layers 310, 310′ and 310″ is approximately equal to the combined thicknesses of its associated polymer layer 308 and bottom foil layer 312, 312′, 312″, respectively. The upper surface of each of the second and third top foil layers 310′ and 310″ may advantageously be pre-coated with a solder plating or cladding 314. The first top foil layer 310 and the second bottom foil layer 312′ are respectively etched to form a set of top isolation gaps 313 and a set of bottom isolation gaps 313′, with each top isolation gap 313 horizontally offset from each bottom isolation gap 313′ by a pre-defined distance.

A plurality of vias 316, 316′, 316″ is formed in each of the substructures 302, 304, 306, respectively. With three substructures as shown, the vias 316 in the upper substructure 302 and the vias 316′ in the lower substructure 304 are in vertical alignment, while the via 316″ in the intermediate substructure 306 is spaced from the other vias 316, 316′ by a predetermined distance that is slightly greater than the length of the electrodes to be formed in the device by the first top foil layer 310 and the bottom foil layers 312, 312′, 312″, as will be described below.

The upper surface of the first top metal layer 310 and the lower surface of the second bottom foil layer 312′ are masked with a suitable insulative or (preferably) dielectric material 315, which fills in the isolation gaps 313, 313′, leaving exposed areas around each via 316 in the top surface of the upper substructure 302 and around each via 316′ in the lower substructure 304, and at the above-defined predetermined distance from each of the vias 316, 316′. These exposed areas are plated with a conductive metal plating to form terminal pads 319a, 319b, 319c, 319d. Each of the vias 316, 316′, 316″ is also internally plated to provide a metal-plated cross-conductor 317 between each of the top foil layers 310, 310′, 310″ and its respective bottom foil layer 312, 312′, 312″. Preferably, a first plating layer of copper is applied, followed by a second plating layer of a solderable metal, such as nickel or gold. Alternatively, a layer of nickel can be plated, followed by a separate layer of gold. It will be appreciated that these masking and plating steps can be performed either while the laminated substructures 302, 304, 306 are separated, or after they are laminated together, as described below. As shown, one of the terminal pads 319a on the upper substructure 302 surrounds the opening of the via 316 through that substructure; likewise, one of the terminal pads 319c on the lower substructure 304 surrounds the opening of the via 316′ through that substructure.

Referring now to FIG. 8B, on the lower laminated substructure 304 and the intermediate laminated substructure 306, an etch-resistant mask (not shown) is applied to the top surfaces of the solder plating layer 314 in an area surrounding each of the vias 316′, 316″, the inside of the vias 316′, 316″, and the bottom surfaces of the second and third bottom foil sheets 312′, 312″ (except for areas that could form optional singulation lines). The unmasked portions of the second and third top foil sheets 310′ and 310″, including the solder plating layer 314, are etched away or otherwise removed, leaving a knob or protrusion 318 centered around each of the 316′, 316″ on the lower and intermediate substructures 304 and 306, which protrusion has a height equal to the combined thickness of the original second and third top foil sheets 310′, 310″, respectively, and the solder plating or cladding layer 314. The etch-resistant mask is then removed, by any suitable technique known in the art.

At a location that would be in registry (vertical alignment) with the protrusion 318 on the adjacent substructure so as to allow the three substructures 302, 304, 306 to be vertically stacked, first and second apertures 320, 322 are respectively formed in each of the first and second bottom foil sheets 312, 312′and in the corresponding polymer layers 308 using mechanical or etching techniques common in the industry. Thus, the first aperture 320 is a blind aperture that terminates at the bottom surface of the first top foil layer 310, while the second aperture 322 forms a passage extending all the way through the intermediate substructure 306. A third aperture 324 is formed in the lower substructure 304, near the end opposite the protrusion 318 of the lower substructure. The third aperture 324 passes through the plated terminal pad 319d, the second bottom foil layer 312′, and the adjacent polymeric layer 308.

The radius of each of the first and second apertures 320, 322 is greater than that of the protrusions 318, preferably by an amount that is approximately equal to the thickness of the polymeric layer 308, thereby allowing the protrusion 318 of the adjacent substructure to fit into the aperture of the adjoining substructure with a substantial annular space surrounding the protrusion. This annular space, as will be shown below, provides an isolation gap between the protrusion and the metal layer through which it passes. With each protrusion 318 seated in its respective aperture 320, 322, the three substructures 302, 304, 306 are vertically stacked, as shown in FIG. 9, in alternating alignment, 180 degrees from each other. After stacking, the three substructures 302, 304, 306 are laminated together using conventional lamination techniques.

During lamination, the solder layer 314 on top of the protrusion 318 extending from the lower substructure 304 is reflowed and bonds to the portion of the underside of the first bottom foil layer 312 on the upper substructure 302 that is exposed through the aperture 322 in the intermediate substructure 306, thereby forming a mechanical bond and an electrical connection with the first bottom foil layer 312. Similarly, during lamination, the solder layer 314 on top of the protrusion 318 extending from the intermediate substructure 306 is re-flowed and bonds to the portion of the underside of the first top foil layer 310 of the upper substructure 302 that is exposed through the aperture 320 in the upper substructure 302, thereby forming a mechanical bond and an electrical connection with the first top foil layer 310. Alternatively, a conductive epoxy may be used instead of the solder layer 314, in which case the pressure and heat of the lamination process cause the formation of the mechanical bond and the electrical connection.

As a result of the lamination process, the material of the polymer layers 308 flows into and substantially fills the annular spaces formed in the apertures 320 and 322 around the respective protrusions 318, thereby isolating protrusions 318 from the adjacent metal foil layers (i.e., first bottom foil layer 312 and the third bottom foil layer 312″). Also, as shown in FIG. 9, in the laminated device 300, each of the vias 316′ in the lower substructure 304 is contiguous with and axially aligned with one of the vias 316 in the upper substructure 302.

After the lamination of the three substructures, the third aperture 324 is used to form a connection between the second bottom foil layer 312′ and the third (interior) bottom foil layer 312″. The interior surfaces of the third aperture 324 are plated with a conductive metal to form an electrical contact element 326 that provides electrical connection between the terminal pad 319d, the third bottom foil layer 312″, and the adjacent plated via 316″. Thus, the plating of the interior of the third aperture 324 and the exposed bottom area of the third bottom foil layer 312″ provides a mechanical and electrical connection from the terminal pad 319d through the third aperture 324 to the third foil layer 312″. Each of the plated vias 316, 316′, 316″ provides a conductive path or cross-conductor 317 between the lower terminal pads 319c, 319d and the upper terminal pads 319a, 319b, respectively, and each of the cross-conductors 317 makes electrical contact with two selected metal layers, while being isolated from the remaining metal layers.

Thus, after singulation, (as described above), which may be centered on the vias 316, 316′, 316″, each device 300 includes first and second terminals, each of which includes a respective lower terminal pad 319c, 319d, a plated via cross-conductor 317, and a respective upper terminal pad 319a, 319b. Furthermore, each singulated device includes an upper electrode 310 formed from the first upper metal foil layer of the upper substructure 302, a lower electrode 312′ formed from the second lower metal foil layer 312′ of the lower substructure 304, and first and second interior electrodes 312, 312″, respectively formed from the first lower metal foil layer of the upper substructure 302 and the third lower metal foil layer of the intermediate substructure 306. The first terminal makes contact with the first interior electrode 312 and lower electrode 312′, while being isolated from the second interior electrode 312″ and the upper electrode 310. The second terminal makes contact with the second interior electrode 312″ and the upper electrode 310 while being isolated from the first interior electrode 312 and lower electrode 312′. It will be appreciated that the method used to manufacture device 300 shown in FIGS. 8A, 8B and 9 can be used to construct a device with more than three polymer layers.

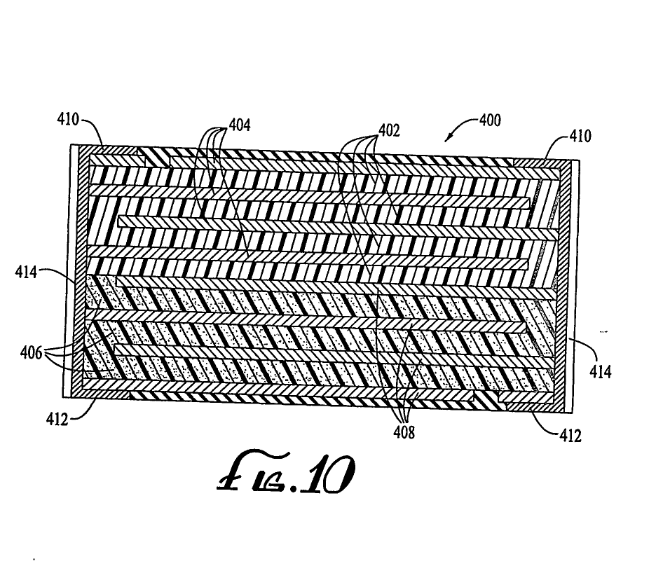

Other types of devices constructed in accordance with the present invention are shown in FIGS. 10-16. For example, FIG. 10 illustrates a device 400 comprising a multi-layer polymeric capacitor in parallel with a polymeric metal oxide varistor (MOV) to protect the capacitor from overvoltages. The device 400 may be constructed in accordance with the method described above in connection with FIGS. 4 and 5. In the capacitor/MOV device 400, a plurality of polymeric dielectric layers 402 are laminated between a first plurality of metal foil layers that form a plurality of capacitor electrodes 404, thereby forming a multi-layer polymeric capacitor structure. A plurality of polymeric MOV layers 406 are laminated between a second plurality of metal foil layers that form a plurality of MOV electrodes 408, thereby forming a multi-layer polymeric MOV structure. The multi-layer polymeric capacitor structure is stacked on top of the multi-layer polymeric MOV structure. Each device 400 is provided with a pair of terminals, each comprising an upper terminal pad 410, a lower terminal pad 412, and an interconnection provided by a plated through-hole via 414.

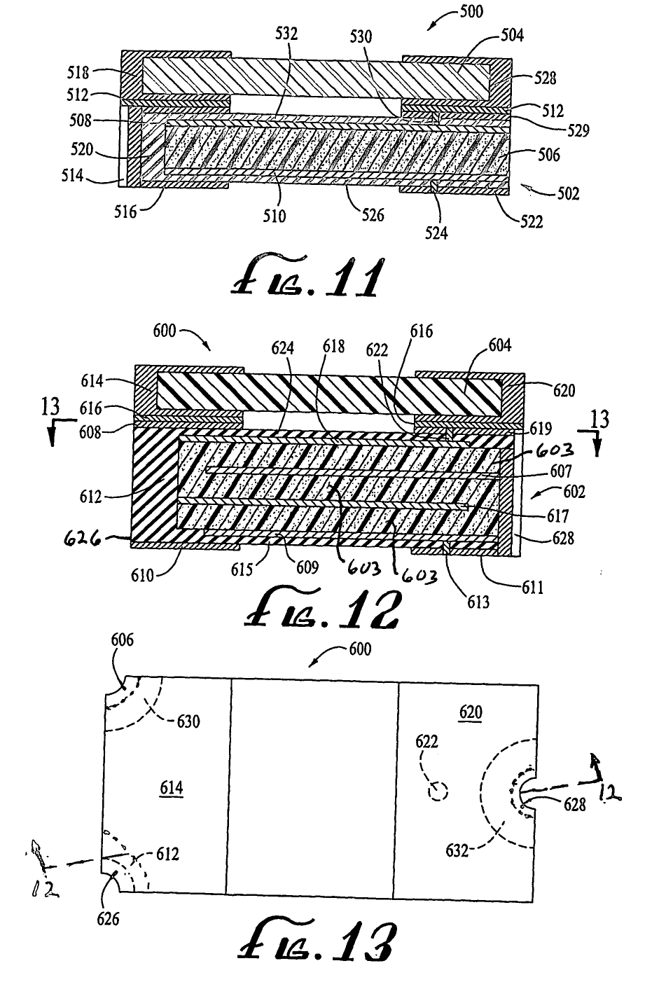

FIG. 11 shows a multi-layer device 500 comprising a single-layer polymer PTC (PPTC) resistive component 502 in series with a laminar polymeric fixed resistor component 504. More specifically, the device 500 comprises a polymer PTC (PPTC) layer 506 laminated between first and second metal foil layers that form upper and lower PPTC electrodes 508, 510, respectively. The polymeric fixed resistor 504 is stacked onto and bonded to the PPTC device 502 with a conductive bonding layer 512 of solder or conductive adhesive. The multi-layer device 500 uses a plated through-hole via 514 to provide an electrically conductive connection (cross-conductor) between a first bottom terminal pad 516 and a first fixed resistor termination 518 through the conductive bonding layer 512. The cross-conductor provided by the plated through-hole via 514 is insulated from the PPTC electrodes 508, 510 by a prepreg-filled isolation area 520 that may be formed in the manner described above in connection with FIGS. 6 and 7. A second bottom terminal pad 522 is electrically connected to the lower PPTC electrode 510 by means of a first plated micro-via 524 that extends through a bottom prepreg insulation layer 526 (applied to the surface of the lower PPTC electrode 510) to the surface of the lower PPTC electrode 510. A second fixed resistor termination 528 is electrically connected to the upper PPTC electrode 508 through the bonding layer 512 and an upper planar termination element 529 by means of a second plated micro-via 530 that extends through a top prepreg layer 532 (applied to the surface of the upper PPTC electrode 508) to the surface of the upper PPTC electrode 508.

Alternatively, a first PPTC terminal may be formed at one end of the lower PPTC electrode 510 by not applying the bottom prepreg insulation layer 526 to that portion of the lower PPTC electrode 510, thereby eliminating the need for the second bottom terminal pad 522 and the first plated micro-via 524. A similarly-formed terminal at one end of the upper PPTC electrode 508 would eliminate the for the upper planar termination element 529 and the second plated micro-via 530.

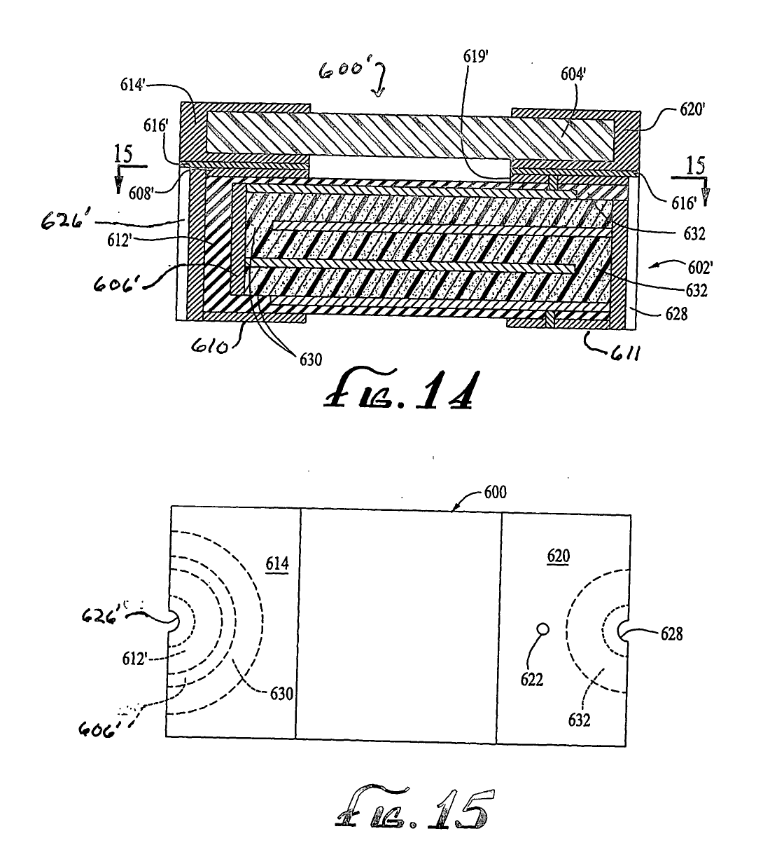

FIGS. 12 and 13 illustrate a multi-layer device 600 comprising a three-layer laminar polymer PTC (PPTC) component 602 in series with a second laminar polymer device 604, which may be a polymer fixed resistor, a battery, a diode, or any other solid state device that can be made in a laminar configuration. The multi-layer device 600 may advantageously be made with a plated through-hole via construction method, as described above in connection with FIGS. 6 and 7, for example. In this embodiment, the PPTC component generally comprises N conductive polymer layers and N+1 laminar metal electrodes, where N is an integer greater than 1. The electrodes comprise a first set of electrodes that includes a lower electrode, and a second set of electrodes that includes an upper electrode. In the specific example shown in FIGS. 12 and 13, the PPTC device 602 comprises three conductive polymer layers 603 laminated between four metal foil electrodes. A first set of electrodes comprises a first internal electrode 607 and a lower electrode 609. A second set of electrodes comprises a second internal electrode 617 and an upper electrode 618.

A first plated through-hole via 606 (FIG. 13) provides a first cross-conductor that electrically connects the second internal PPTC device electrode 617 and the upper PPTC device electrode 618. A second plated through-hole via 628 electrically provides a second cross-conductor that electrically connects the first internal PPTC device electrode 607 and the lower PPTC device electrode 609. The first and second cross-conductors respectively formed by the first and second through-hole vias 606, 628 are electrically isolated from the electrodes to which they are not connected by first and second isolation areas 630, 632, respectively, formed by the removal of portions of the metal layers forming the electrodes, as described above. In this arrangement, the three conductive polymer layers 603 are connected in parallel.

The lower PPTC device electrode 609 is electrically connected to a first bottom PPTC terminal pad 611, on the bottom surface of the PPTC component 602, by means of a first plated micro-via 613 that extends through a bottom insulating prepreg layer 615 (applied to the bottom surface of the lower PPTC device electrode 609). The upper PPTC device electrode 618 is electrically connected to a first PPTC device top terminal pad 619, on the top surface of the PPTC component 602, by a plated micro-via 622 that extends through a top insulating prepreg layer 624 (applied to the top surface of the upper PPTC device electrode 618).

The PPTC device 602 and the second polymer device 604 are connected in series as follows: A first electrical connection is made between the first PPTC device top terminal pad 619 and a first terminal 620 of the second polymer device 604 through a re-flowed solder bonding layer 616 that bonds the PPTC device 602 to the second polymer device 604. Similarly, a second electrical connection is made between a second PPTC device top terminal pad 608, on the top surface of the PPTC component 602, and a second terminal 614 of the second polymer device 604. A third plated through-hole via 626 (FIG. 13) electrically connects the second PPTC device top terminal pad 608 to a second PPTC device bottom terminal pad 610, on the bottom surface of the PPTC component 602, thereby completing the series connection between the two devices 602, 604. The third plated through-hole via 626 is surrounded by an arcuate insulation structure 612, formed of prepreg, that fills a space formed by the removal of portions of the metal layers that form the electrodes of the PTC device, as described above, such that the third plated through-hole via 626 is isolated from the PTC device electrodes 607, 609, 617, 618.

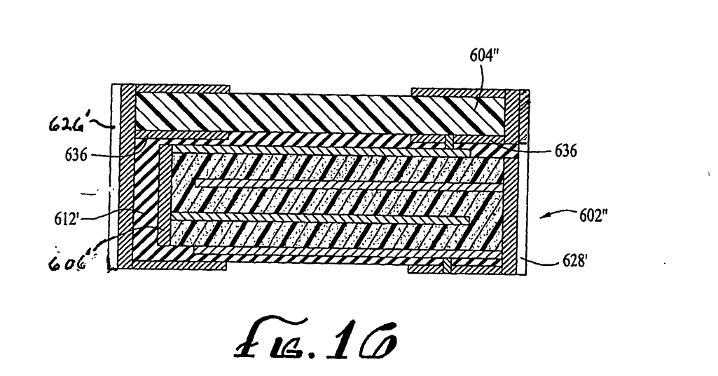

FIGS. 14 and 15 show a multi-layer device 600′ that is a modification of the embodiment of FIGS. 12 and 13, in which the third plated through-hole via 626′ is formed concentrically within a larger-diameter first plated through-hole via 606′. The first plated through-hole via 606′ is insulated from the third plated through-hole via 626′ by a prepreg-filled isolation area 612′. The larger-diameter first plated through-hole via 606′ is electrically isolated from the electrodes to which it is not connected by isolation areas 630. As in the embodiment of FIGS. 12 and 13, in the modified embodiment of FIGS. 14 and 15, the terminals 608′, 619′ of the PTC device 602′ are respectively connected to the terminals 614′, 620′ of the second polymer device 604′ through a bonding layer 616′. In FIG. 16 it is shown that the bonding layer can be omitted by having the second polymer device 604″ and the PTC device 602″ share a pair of common upper termination pads 636.

It will be appreciated that the embodiments of the invention described above with reference to FIGS. 12-16 may also be constructed so as to incorporate a fourth plated through-hole via (not shown) that is electrically isolated from the second plated through-hole via 628. In this modification, the fourth plated through-hole via electrically connects the first PPTC device top terminal pad 619, 619′ with a third PPTC device bottom terminal pad (not shown) using construction methods similar to those used to make the first plated through hole via 626, 626′ and the third plated through-hole via 606, 606′ described above to isolate the fourth plated through-hole via from the second plated through-hole via 628. The third bottom PPTC terminal pad is electrically isolated from the first bottom PPTC terminal pad 611, and is located parallel to it or adjacent to it on the bottom surface of the multi-layer device 600, 600′.

In the devices described above, the uppermost and lowermost layers of the polymer devices may be trimmed by any suitable means, such as by mechanical trimmers, lasers, chemical agents, etc., to improve the tolerances of the devices. This trimming might be performed while the devices are attached in matrix form, if the devices are electrically isolated. Alternatively, trimming can be performed after singulation.

It will be appreciated that the polymer structures discussed above may be made as PTC devices, fixed resistors, capacitors, ferromagnetic devices (e.g., inductors), negative temperature coefficient (NTC) devices, batteries, etc. For example, one or more resistive devices (fixed, PTC, or NTC) can be combined with one or more capacitive or inductive devices, in series, in parallel, or in series/parallel combinations.

It will also be appreciated that the metal foil layers described above may include fired cermet resistors or capacitors. Once fired, these components can be assembled into modules using the manufacturing methods described above.

Finally, it will be understood that the devices described above may be produced, using the methods of the invention, in a variety of packages, either leaded, leadless. Such packages may employ such termination designs as ball grid array (BGA), pad grid array (PGA), single in-line pin (SIP), or dual in-line pin (DIP).

What is claimed is:

1. A method of manufacturing a multi-layer, laminar electronic device, comprising the steps of:
(a) forming a first sheet structure comprising a first layer of non-metallic material between a first upper metal layer and a lower metal layer to form a first sheet structure;
(b) forming a second sheet structure comprising a second upper metal layer over a second layer of non-metallic material;
(c) removing a portion of the first upper metal layer at pre-defined isolation area locations to form a plurality of isolation areas;
(d) forming a multi-layer laminated structure by laminating the first sheet structure to the second sheet structure so that the first upper metal layer is laminated between the first and second non-metallic layers, whereby non-metallic material from the second layer of non-metallic material fills the isolation areas;
(e) forming a plurality of through-hole vias at pre-defined via locations through the laminated structure, each via in a first subset of the plurality of through-hole vias being formed through the isolation areas, and each via in a second subset of the plurality of through-hole vias being formed at a first pre-defined distance from a via in the first subset;
(f) forming a set of transverse top isolation gaps in the second upper metal layer and a set of transverse bottom isolation gaps in the lower metal layer, each of the top transverse isolation gaps being located at a second pre-defined distance from a via in the second subset of vias, and each of the bottom transverse isolation gaps being located at a third pre-defined distance from a via in the second subset of vias;
(g) applying a bottom layer of dielectric material to the lower metal layer so as to fill in the bottom isolation gaps, and so as to leave a plurality of bottom exposed areas surrounding each of the vias, and applying a top layer of dielectric material to the second upper metal layer so as to fill in the top isolation gaps, and so as to leave a plurality of top exposed areas surrounding each of the vias; and
(h) metal-plating the bottom and top exposed areas and the interiors of the first and second subsets of through-hole vias so as to form (1) a first set of terminals through the first subset of vias, each of the first set of terminals being isolated from the first upper metal layer by the non-metallic material filling the isolation areas, and (2) a second set of terminals through the second subset of vias, each of the second set of terminals being in contact with the first upper metal layer.

2. An electronic device manufactured by the method of claim 1.

3. The method of claim 1, wherein at least one of the non-metallic layers comprises a conductive polymer.

4. The method of claim 1, wherein the non-metallic layers are made of a material selected from the group consisting of at least one of a conductive polymer, a dielectric polymer, a fixed resistivity polymer, a metal oxide, and a ferromagnetic polymer.

5. The method of claim 1, wherein the step of forming the first sheet structure includes the step of laminating the first non-metallic layer between the lower metal layer and the first upper metal layer.

6. The method of claim 1, wherein the first non-metallic layer has upper and lower surfaces, and wherein the step of forming the first sheet structure includes the step of metallizing the upper and lower surfaces by a process selected from the group consisting of at least one of metal-plating, screen printing, and vapor deposition.

7. The method of claim 1, wherein the step of forming the second sheet structure includes the steps of:
(c)(1) laminating the second non-metallic layer between the second upper metal layer and a second lower metal layer; and
(c)(2) removing the second lower metal layer.

8. The method of claim 1, wherein the second non-metallic layer has upper and lower surfaces, and wherein the step of forming the second sheet structure includes the step of metallizing the upper and lower surfaces by a process selected from the group consisting of at least one of metal-plating and vapor deposition.

9. The method of claim 1, wherein the second and third pre-defined distances are approximately equal.

10. A multi-layer electronic device, comprising:
N non-metallic laminar elements, where N is an integer greater than 1;
first and second electrically conductive terminals; and
N+1 electrically conductive metal foil electrodes;
wherein the electrodes and the non-metallic laminar elements are laminated together in a structure in which the electrodes and the non-metallic laminar elements are in an alternating relationship, and wherein each electrode makes electrical contact with only one of the first and second terminals.

11. The multi-layer electronic device of claim 10, wherein the non-metallic laminar elements are electrically connected in parallel.

12. The multi-layer electronic device of claim 10, wherein at least one of the N non-metallic laminar elements is a conductive polymer element.

13. The multi-layer electronic device of claim 10, wherein at least one of the N non-metallic laminar elements is a PPTC element.

14. The multi-layer electronic device of claim 1, wherein the multi-layer device has a substantially planar upper surface, and wherein the first terminal includes a substantially planar first terminal pad on the upper surface, and wherein the second terminal includes a second terminal pad on the upper surface.

15. The multi-layer electronic device of claim 14, further comprising an electrical element having third and fourth substantially planar terminal pads that are respectively connected to the first and second terminal pads.

16. The multi-layer electronic device of claim 15, wherein the electrical element is selected from the group consisting of at least one of a capacitive element, a battery, a fixed resistive element, a diode, a ferromagnetic element, and a metal oxide varistor.

17. A multi-layer electronic device, comprising:
a first laminar component comprising a conductive polymer layer between upper and lower metal electrodes, the first laminar component defining top and bottom surfaces;
a first lower terminal pad on the bottom surface and in electrical contact with the lower electrode;
a second lower terminal pad on the bottom surface, spaced from the first lower terminal pad;
a first upper terminal pad on the top surface and in electrical contact with the upper electrode;
a second upper terminal pad on the top surface, spaced from the first upper terminal pad;
a cross-conductor electrically connecting the second lower terminal pad and the second upper terminal pad, and electrically isolated from the upper and lower electrodes; and
a second laminar component having a first terminal electrically and mechanically connected to the first upper terminal pad, and a second terminal electrically and mechanically connected to the second upper terminal pad, whereby the first and second laminar components are electrically connected in series.

18. The multi-layer electronic device of claim 17, wherein the first laminar component comprises a conductive polymer layer laminated between upper and lower metal foil electrodes.

19. The multi-layer electronic device of claim 17, wherein the cross-conductor comprises a metallized via extending between the second upper terminal pad and the second lower terminal pad, and separated from the upper and lower electrodes by an insulative structure.

20. The multi-layer electronic device of claim 19, wherein the insulative structure is formed of prepreg.

21. The multi-layer electronic device of clam 17, wherein the first lower terminal pad is connected to the lower electrode by a first metal-filled micro-via, and wherein the first upper terminal pad is connected to the upper electrode by a second metal-filled micro-via.

22. A multi-layer electronic device, comprising:
a first laminar component comprising N conductive polymer layers, where N is an integer greater than 1, and N+1 metal electrodes, wherein the N+1 electrodes includes a first set of electrodes that includes a lower electrode and a second set of electrodes that includes an upper electrode, the first laminar component having top and bottom surfaces;
a first lower terminal pad on the bottom surface and in electrical contact with the lower electrode;
a second lower terminal pad on the bottom surface, spaced from the first lower terminal pad;
a first upper terminal pad on the top surface and in electrical contact with the upper electrode;
a second upper terminal pad on the top surface, spaced from the first upper terminal pad;
a first cross-conductor electrically connecting the first set of electrodes while being electrically isolated from the second set of electrodes;
a second cross-conductor electrically connecting the second set of electrodes while being electrically isolated from the first set of electrodes, whereby the first and second cross-conductors electrically connect the N conductive polymer layers in parallel;
a third cross-conductor electrically connecting second lower terminal pad and the second upper terminal pad while being electrically isolated from the first and second sets of electrodes; and
a second laminar component having a first terminal electrically and mechanically connected to the first upper terminal pad, and a second terminal electrically and mechanically connected to the second upper terminal pad, whereby the first and second laminar components are electrically connected in series.

23. The multi-layer electronic device of claim 22, wherein the first laminar component comprises N conductive polymer layers laminated between N+1 metal foil electrodes.

24. The multi-layer electronic device of claim 22, wherein the first cross-conductor is a first metallized via extending between the second upper terminal pad and the second lower terminal pad, and separated from the second set of electrodes by at least one first isolation area;
wherein the second cross-conductor is a second metallized via extending between the first upper terminal pad and the first lower terminal pad, and separated from the first set of electrodes by at least one second isolation area; and
wherein the third cross-conductor is a third metallized via extending between the second upper terminal pad and the second lower terminal pad, and separated from the first and second sets of electrodes by an insulative structure.

25. The multi-layer electronic device of claim 24, wherein the insulative structure is formed of prepreg.

26. The multi-layer electronic device of clam 22, wherein the first lower terminal pad is connected to the lower electrode by a first metal-filled micro-via, and wherein the first upper terminal pad is connected to the upper electrode by a second metal-filled micro-via.

27. A multi-layer electronic device, comprising:
a first laminar component comprising N conductive polymer layers, where N is an integer greater than 1, and N+1 metal electrodes, wherein the N+1 electrodes includes a first set of electrodes that includes a lower electrode and a second set of electrodes that includes an upper electrode, the first laminar component having top and bottom surfaces;
a first cross-conductor in electrical contact with the first set of electrodes and electrically isolated from the second set of electrodes;
a second cross-conductor in electrical contact with the second set of electrodes and electrically isolated from the first set of electrodes, whereby the first and second cross-conductors electrically connect the N conductive polymer layers in parallel; and
a second laminar component having a first and second terminals attached to the top surface of the first laminar component, the first terminal being electrically connected to the upper electrode, and the second terminal being provided by a third cross-conductor concentric with and electrically isolated from the first cross-conductor, whereby the first and second laminar components are electrically connected in series.

28. The multi-layer electronic device of claim 27, wherein the first laminar component comprises N conductive polymer layers laminated between N+1 metal foil electrodes.

29. The multi-layer electronic device of claim 27, wherein the first cross-conductor is a first through-hole via with a metallized surface in contact with the first set of electrodes and separated from the second set of electrodes by at least one first isolation area;
wherein the second cross-conductor is a second through-hole via with a metallized surface in contact with the second set of electrodes, and separated from the first set of electrodes by at least one second isolation area; and
wherein the third cross-conductor is a third through-hole via having a metallized surface, the third through-hole via being coaxial with the first through-hole via and separated therefrom by an insulative structure.

30. The multi-layer electronic device of claim 29, wherein the insulative structure is formed of prepreg.

31. The multi-layer electronic device of claim 27, further comprising:
a first lower terminal pad on the bottom surface; and in electrical contact with the lower electrode
a second lower terminal pad on the bottom surface, spaced from the first lower contact pad.

32. The multi-layer electronic device of clam 31, wherein the first lower terminal pad is connected to the lower electrode by a lower metal-filled micro-via.

33. The multi-layer electronic device of claim 32, further comprising:
a first upper terminal pad on the top surface; and
a second upper terminal pad on the top surface, spaced from the first upper contact pad.

34. The multi-layer electronic device of clam 33, wherein the first upper terminal pad is connected to the upper electrode by an upper metal-filled micro-via.

35. The multi-layer electronic device of claim 34, wherein the first terminal of the second laminar component is mechanically and electrically connected to the first upper terminal pad, and wherein the second terminal of the second laminar component is mechanically and electrically connected to the second upper terminal pad.
